(19) United States
(12) Patent Application Publication
(10) Pub. No.: US 2026/0194593 A1
(43) Pub. Date: Jul. 9, 2026

(54) METHOD FOR VEHICLE BATTERY CELL LIFE PREDICTION

(71) Applicant: GM Global Technology Operations LLC, Detroit, MI (US)

(72) Inventors: Jingyuan Liu, Shanghai (CN); Xin Zhang, Shanghai (CN); Si Chen, Shanghai (CN); Haijing Liu, Shanghai (CN); Lei Wang, Rochester Hills, MI (US); Ratandeep Singh Kukreja, Auburn Hills, MI (US); Robert Dale Burns, Lake Orion, MI (US)

(21) Appl. No.: 19/033,833

(22) Filed: Jan. 22, 2025

(30) Foreign Application Priority Data
Jan. 6, 2025 (CN) 202510018601.3

(51) Int. Cl. G01R 31/392; B60L 50/64; G01R 31/367; G01R 31/382; H01M 10/42

(52) U.S. Cl. CPC G01R 31/392; B60L 50/64; G01R 31/367; G01R 31/382; H01M 10/425; B60L 2250/16

(57) ABSTRACT

A method for predicting battery cell life for lithium-based battery cells is provided. The method includes receiving a predetermined end-of-life pressure, tracking an onboard battery cell pressure change between battery cells, determining a pressure between the battery cells, and determining if the pressure is greater than a pre-end-of-life warning pressure. If the pressure is less than the pre-end-of-life warning pressure, then the method includes providing the pressure to at least partially determine the onboard battery cell pressure change. If the pressure is greater than the pre-end-of-life warning pressure, then the method includes determining if the pressure is greater than the predetermined end-of-life pressure. If the pressure is less than the predetermined end-of-life pressure, then the method includes providing a pre-warning failure indication. If the pressure is greater than or equal to the predetermined end-of-life pressure, then the method includes providing an indication of failure.

### INTRODUCTION

The present disclosure relates to a vehicle battery pack and battery cells, and more particularly, to a method for predicting battery cell life.

Electric and hybrid electric vehicle technology is enabled by the development and deployment of rechargeable, secondary batteries, which provide energy to the vehicle powertrain. Secondary batteries include lithium ion batteries, which generally include a cathode, anode, and electrolyte. The cathode provides a source of lithium ions and determines capacity and average voltage of a battery. The anode stores and releases lithium ions received from the cathode when energy is needed. The electrolyte provides a medium between the cathode and anode through which the lithium ions travel.

Battery cells, especially lithium iron phosphate (LFP/Li) cells, are highly likely to have a “sudden death” at their end-of-life or failure. Before the battery cell end-of-life, there is no obvious detectable capacity decay leading to challenges in life prediction of these LFP/Li battery cells.

Thus, while battery cells achieve their intended purpose, there is a need for new and improved method for predicting battery cell life.

### SUMMARY

According to several aspects of the present disclosure, a method for predicting battery cell life for lithium-based battery cells is provided. The method includes receiving a predetermined end-of-life pressure P₁ for a lithium-based battery cell, tracking an onboard battery cell pressure change using a pressure sensor disposed between a first battery cell and a second battery cell in the vehicle battery pack, determining a pressure P between the first battery cell and the second battery cell at least partially based on the predetermined end-of-life pressure P₁ and the onboard battery cell pressure change, and determining if the pressure P is greater than a pre-end-of-life warning pressure P₀. If the pressure P is less than the pre-end-of-life warning pressure P₀, then the method includes providing the pressure P to at least partially determine the onboard battery cell pressure change. If the pressure P is greater than the pre-end-of-life warning pressure P₀, then the method includes determining if the pressure P is greater than or equal to the predetermined end-of-life pressure P₁. If the pressure P is less than the predetermined end-of-life pressure P₁, then the method includes providing a pre-warning signal indication to at least partially determine the onboard battery cell pressure change. If the pressure P is greater than or equal to the predetermined end-of-life pressure P₁, then the method includes providing an indication of battery cell failure. The lithium-based battery cell is disposed in a vehicle battery pack.

In accordance with another aspect of the disclosure, the predetermined end-of-life pressure P₁ is determined using lab testing.

In accordance with another aspect of the disclosure, the predetermined end-of-life pressure P₁ is predetermined using empirical model prediction.

In accordance with another aspect of the disclosure, the pressure sensor includes a one-dimensional (1D) pressure sensor.

In accordance with another aspect of the disclosure, the pressure sensor includes a two-dimensional (2D) pressure sensor.

In accordance with another aspect of the disclosure, determining the pressure P between the first battery cell and the second battery cell is at least partially based on the predetermined end-of-life pressure and the onboard battery cell pressure change occurs when a state of charge (SOC) is 100%.

In accordance with another aspect of the disclosure, determining a pressure P includes determining a thickness of the first battery cell and the second battery cell using at least one thickness sensor.

In accordance with another aspect of the disclosure, determining the thickness of the first battery cell and the second battery cell includes using a one-dimensional (1D) thickness sensor.

In accordance with another aspect of the disclosure, determining the thickness of the first battery cell and the second battery cell includes using multiple thickness sensors.

In accordance with another aspect of the disclosure, determining the pressure P between the first battery cell and the second battery cell includes determining an average pressure and variation between at least three battery cells.

In accordance with another aspect of the disclosure, the pressure P is caused by irreversible swelling of the first battery cell and the second battery cell.

In accordance with another aspect of the disclosure, the pre-end-of-life warning pressure P₀ is predetermined to be 80% of the predetermined end-of-life pressure P₁.

In accordance with another aspect of the disclosure, the pre-end-of-life warning pressure P₀ is predetermined to be 90% of the predetermined end-of-life pressure P₁.

In accordance with another aspect of the disclosure, the lithium-based battery cell includes a lithium-based anode.

In accordance with another aspect of the disclosure, the lithium-based battery cell includes at least one of a LFP, NCM/NCA/NCMA/NMx, LMR, or a sulfur-based cathode.

In accordance with another aspect of the disclosure, the lithium-based battery cell includes an ester-based electrolyte.

In accordance with another aspect of the disclosure, the lithium-based battery cell is at least one of a pouch-type, a cylindrical-type, or a prismatic-type.

According to several aspects of the present disclosure, a method for predicting battery cell life for lithium-based battery cells is provided. The method includes receiving a predetermined end-of-life pressure P₁ for a lithium-based battery cell having a finalized electrolyte amount and electrode amount, tracking an onboard battery cell pressure change using a pressure sensor disposed between a first battery cell and a second battery cell in the vehicle battery pack when a state of charge (SOC) of the lithium-based battery cell is 100%, determining a pressure P between the first battery cell and the second battery cell at least partially based on the predetermined end-of-life pressure and the onboard battery cell pressure change, and determining if the pressure P is greater than a pre-end-of-life warning pressure P₀. If the pressure P is less than the pre-end-of-life warning pressure P₀, then the method includes providing a state of health (SOH) battery cell pressure to at least partially determine the onboard battery cell pressure change. If the pressure P is greater than the pre-end-of-life warning pressure P₀, then the method includes determining if the pressure P is greater than or equal to the predetermined end-of-life pressure P₁. If the pressure P is less than the predetermined end-of-life pressure P₁, then the method includes providing a pre-warning signal indication to at least partially determine the onboard battery cell pressure change. If the pressure P is greater than or equal to the predetermined end-of-life pressure P₁, then the method includes providing an indication of battery cell failure. The lithium-based battery cell is disposed in a vehicle battery pack.

In accordance with another aspect of the disclosure, determining the pressure P between the first battery cell and the second battery cell includes determining an average pressure between at least two battery cells.

According to several aspects of the present disclosure, a system for predicting battery cell life for lithium metal-based cells is provided. The system includes a human-machine interface and a controller in electrical communication with the human machine interface. The controller is programmed to receive a predetermined end-of-life pressure P₁ for a lithium-based battery cell having a finalized electrolyte amount and electrode amount, track an onboard battery cell pressure change using a pressure sensor disposed between multiple battery cells in the vehicle battery pack when a state of charge (SOC) of the lithium-based battery cell is 100%, determine a pressure P between the multiple battery cells at least partially based on the predetermined end-of-life pressure and the onboard battery cell pressure change, and determine if the pressure P is greater than a pre-end-of-life warning pressure P₀. If the pressure P is less than the pre-end-of-life warning pressure P₀, then the controller is programmed to provide a state of health (SOH) battery cell pressure to at least partially determine the onboard battery cell pressure change. If the pressure P is greater than the pre-end-of-life warning pressure P₀, then the controller is programmed to determine if the pressure P is greater than or equal to the predetermined end-of-life pressure P₁. If the pressure P is less than the predetermined end-of-life pressure P₁, then the controller is programmed to provide a pre-warning signal indication to at least partially determine the onboard battery cell pressure change. If the pressure P is greater than or equal to the predetermined end-of-life pressure P₁, then the controller is programmed to provide an indication of battery cell failure. The lithium-based battery cell is disposed in a vehicle battery pack.

The above features and advantages, and other features and advantages, of the presently disclosed system and method are readily apparent from the detailed description, including the claims, and examples when taken in connection with the accompanying drawings.

### BRIEF DESCRIPTION OF THE DRAWINGS

The present disclosure will become more fully understood from the detailed description and the accompanying drawings, wherein:

FIG. 1 is a schematic view illustrating an example of a vehicle having an electric motor powered by a battery pack having an LFP/Li-based chemistry, in accordance with the present disclosure.

FIG. 2 is a cross section schematic view of a battery pack in the vehicle shown in FIG. 1, where the battery pack includes a plurality of LFP/Li battery cells and a plurality of pressure sensors, in accordance with the present disclosure.

FIG. 3 is a cross section view of a battery cell in the battery pack shown in FIG. 2, where a pressure sensor is disposed proximate to the battery cell, in accordance with the present disclosure.

FIG. 4 is a cross section view of a battery cell in the battery pack shown in FIG. 2, where multiple pressure sensors/two dimensional (2D) film sensors are disposed proximate to the battery cell, in accordance with the present disclosure.

FIG. 5 is a cross section view of a battery cell in the battery pack shown in FIG. 2, where a thickness sensor is disposed proximate to the battery cell, in accordance with the present disclosure.

FIG. 6 is a cross section view of a battery cell in the battery pack shown in FIG. 2, where multiple thickness sensors are disposed proximate to the battery cell, in accordance with the present disclosure.

FIG. 7 is a flowchart illustrating a method for predicting battery cell life for the lithium-based cells shown in FIGS. 2 through 6, in accordance with the present disclosure.

### DETAILED DESCRIPTION

The following description is merely exemplary in nature and is not intended to limit the present disclosure, application, or uses. Furthermore, there is no intention to be bound by any expressed or implied theory presented in the preceding introduction, summary, or the following detailed description. It should be understood that throughout the drawings, corresponding reference numerals indicate like or corresponding parts and features.

Reference will now be made in detail to several examples of the disclosure that are illustrated in accompanying drawings. Whenever possible, the same or similar reference numerals are used in the drawings and the description to refer to the same or like parts or steps. The drawings are in simplified form and are not to precise scale. The following description is merely exemplary in nature and is not intended to limit the present disclosure, application, or uses.

For battery cells, especially lithium metal anode-based battery cells, “sudden death” properties and end-of-life are often difficult to predict because, before the end-of-life, there is no obvious capacity decay that is trackable. The capacity of the battery cell is not linear near the end-of-life compared to the number of cycles. The method and subject matter disclosed herein are designed to link a battery cell life with swelling status of the battery cells because irreversible swelling of the battery cell is at least somewhat linear compared to the number of cycles of the battery cell. By using this reliable and detectable method, the lithium battery cell life becomes predictable. This method may be utilized for lithium iron phosphate (LFP)-type batteries as well as lithium sulfur (Li-S)-type batteries, nickel cobalt manganese (NCM/Li)-type batteries.

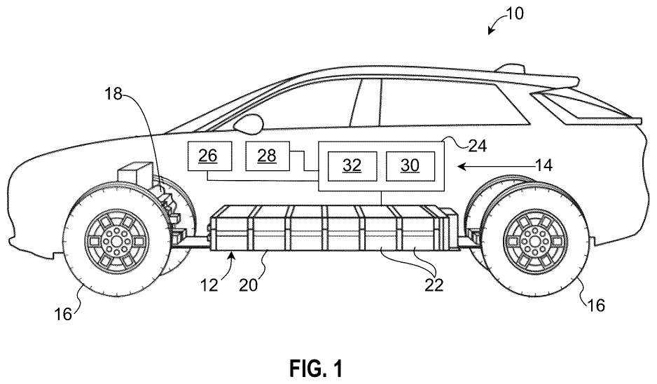

Referring to FIG. 1, a perspective view of a vehicle 10 having a battery pack 12 and a system 14 for predicting battery cell life for lithium metal-based cells is illustrated, in accordance with the present disclosure. The battery pack 12 is illustrated with an exemplary vehicle 10. The vehicle 10 is an electric vehicle or hybrid vehicle having wheels 16 driven by at least one electric motor/inverter 18. The electric motors/inverters 18 receive power from the battery pack 12. While the vehicle 10 is illustrated as a passenger road vehicle, it should be appreciated that the battery pack 12 may be used with various other types of vehicles. For example, the battery pack 12 may be used in nautical vehicles, such as boats, or aeronautical vehicles, such as drones or passenger airplanes. Moreover, the battery pack 12 may be used as a stationary power source separate and independent from a vehicle. Battery pack 12 includes a housing 20 for carrying and supporting a plurality of battery cells 22. In an example, the battery pack 12 may have fifty or more battery cells 22.

As used herein, the term “vehicle” is not limited to automobiles. While the present technology is described primarily herein in connection with electric and hybrid-electric vehicles, the technology is not limited to electric and hybrid-electric vehicles. The concepts can be used in a wide variety of applications, such as in connection with components used in motorcycles, mopeds, locomotives, aircraft, marine craft, and other vehicles, as well as in other applications utilizing batteries, such as in portable power stations, such as those used for powering remote job sites, emergency back-up power supplies, and permanent power stations associated with buildings and equipment, all of which may be powered by, for example, solar or wind-powered generator systems, power mains, and fuel based power generators such as gasoline, propane, kerosene, or diesel generators as well as sterling engines.

The system 14 is shown with the vehicle 10. The system 14 generally includes a controller 24, a human-machine interface (HMI) 26, and/or a heads-up display (HUD) 28.

The controller 24 is used to implement a method 100 for predicting battery cell life for lithium metal-based cells, as will be described below. The controller 24 includes at least one processor 30 and a non-transitory computer readable storage device or media 32. The processor 30 may be a custom made or commercially available processor, a central processing unit (CPU), a graphics processing unit (GPU), an auxiliary processor among several processors associated with the controller 24, a semiconductor-based microprocessor (in the form of a microchip or chip set), a macroprocessor, a combination thereof, or generally a device for executing instructions.

The computer readable storage device or media 32 may include volatile and nonvolatile storage in read-only memory (ROM), random-access memory (RAM), and keep-alive memory (KAM), for example. KAM is a persistent or non-volatile memory that may be used to store various operating variables while the processor 30 is powered down. The computer-readable storage device or media 32 may be implemented using a number of memory devices such as PROMs (programmable read-only memory), EPROMs (electrically PROM), EEPROMs (electrically erasable PROM), flash memory, or another electric, magnetic, optical, or combination memory devices capable of storing data, some of which represent executable instructions, used by the controller 24 to control various systems of the vehicle 10.

The controller 24 may also consist of multiple controllers which are in electrical communication with each other. The controller 24 may be inter-connected with additional systems and/or controllers of the vehicle 10, allowing the controller 24 to access data such as, for example, battery condition, vehicle speed, acceleration, braking, and steering angle of the vehicle 10.

The controller 24 is in electrical communication with the HMI 26 and the HUD 28. In an exemplary embodiment, the electrical communication is established using, for example, a CAN network, a FLEXRAY network, a local area network (e.g., WiFi, ethernet, and the like), a serial peripheral interface (SPI) network, or the like. It should be understood that various additional wired and wireless techniques and communication protocols for communicating with the controller 24 are within the scope of the present disclosure. It should be understood that the HMI 26 and/or the HUD 28 may be integrated with the controller 24 (e.g., on a same circuit board with the controller 24 or otherwise a part of the controller 24) without departing from the scope of the present disclosure. It should further be understood that, in the scope of the present disclosure, electrical communication also includes power and/or energy transfer between electrical devices (e.g., using conducting wires and/or wireless power transmission techniques).

The HMI 26 is used to provide information to an occupant of the vehicle 10. In the scope of the present disclosure, the occupant includes a driver and/or a passenger of the vehicle 10. In the exemplary embodiment depicted in FIG. 1, the HMI 26 is a display (e.g., part of an infotainment system of the vehicle 10) located in view of the occupant and capable of displaying text, graphics, and/or images. It is to be understood that HMI display systems including LCD displays, LED displays, and the like are within the scope of the present disclosure. Further exemplary embodiments where the HMI 26 is disposed in a rearview mirror are also within the scope of the present disclosure. In an exemplary embodiment, the HMI 26 may include a human-interface device (HID), including, for example, a touchscreen, an electromechanical switch, a capacitive switch, a rotary knob, a microphone for receiving voice commands, and the like. It should be understood that additional systems for displaying information to the occupant of the vehicle 10 are also within the scope of the present disclosure. The HMI 26 is in electrical communication with the controller 24 as discussed above.

The HUD 28 is used to provide information to the occupant of the vehicle 10. In an exemplary embodiment, the HUD 28 is configured to provide information to the occupant by projecting text, graphics, and/or images upon a windscreen of the vehicle 10. In a non-limiting example, the HUD 28 includes a projector (not shown) which is used by the controller 24 to project the text, graphics, and/or images (e.g., a battery cell life or condition) upon the windscreen of the vehicle 10. The text, graphics, and/or images are reflected by the windscreen of the vehicle 10 and are visible to the occupant without looking away from a roadway ahead of the vehicle 10. It should be understood that diverse types of head-up display devices, including, for example, augmented reality head-up display (AR-HUD) devices are within the scope of the present disclosure. It should be understood that additional systems for displaying information to the occupant of the vehicle 10 are also within the scope of the present disclosure. The HUD 28 is in electrical communication with the controller 24 as discussed above.

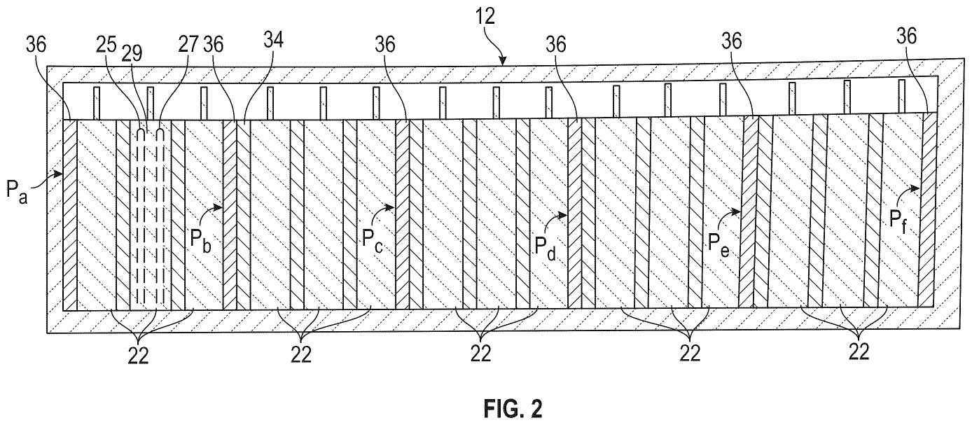

FIG. 2 illustrates a plurality of battery cells 22 within the battery pack 12 illustrated in FIG. 1. The battery pack 12 and the battery cells 22 are understood to be rechargeable batteries that may be discharged upon application of a load and recharged upon the application of an external power source. While the battery cells 22 are shown as prismatic-type battery cells, the battery cells 22 may also include, for example, pouch-style cells and/or cylindrical-style cells.

Each battery cell 22 disposed within the battery pack 12 shown in FIG. 1 includes at least one cathode 25, at least one anode 27, and/or an electrolyte 29. The cathode(s) 25 and the anode(s) 27 are placed in the battery cell 22, which is filled with an electrolyte 29. The electrolyte 29 transports ions between the cathode 25 and the anode 27.

During discharge and when a load is applied to the battery cells 22, Li+ ions move from the anode 27 to the cathode 25 by way of the electrolyte 29. Equivalent electrons e⁻ move through battery circuitry from the cathode 25 to the anode 27, providing energy to a battery load. While charging and upon application of an external voltage, Li⁺ ions move from the cathode 25 to the anode 27 by way of the electrolyte 29 and may be intercalated into the anode 27.

Each battery cell 22, such as that illustrated in FIG. 2, generally includes the cathode 25 disposed on a cathode current collector (not shown), the anode 27 disposed on an anode current collector (not shown), and the electrolyte 29. While the illustrated battery cells 22 show one anode 27 and one cathode 25, the battery cell 22 may include two or more cathodes 25 and two or more anodes 27.

The cathode 25 includes a cathode active material that provides a source of lithium ions (Li⁺) and can undergo reversible insertion or intercalation of lithium ions determining, for example, the capacity and average voltage of a battery. In embodiments, the active material may include lithium iron phosphate (LFP), lithium manganese iron phosphate (LMFP), nickel cobalt manganese (NCM), nickel cobalt aluminum (NCA), nickel, cobalt, manganese, and aluminum (NCMA), nickel manganese (NMx), lithium manganese rich (LMR), and/or sulfur. The active cathode material may include different blend mass ratios of the components.

The anode 27 includes materials that can undergo reversible insertion or intercalation of lithium ions at a lower electrochemical potential than the cathode 25 material, such that an electrochemical potential difference exists between the anode 27 and cathode 25. The anode 27 may include one or more of lithium metal; alloys of lithium for example lithium silicon alloy, lithium aluminum alloy, lithium indium alloy, lithium titanate, and lithium tin alloy; carbon based materials for example graphite, activated carbon, carbon black and graphene; silicon; silicon based alloys; silicon oxide; silicon based composite materials; tin oxide; aluminum; indium; zinc; germanium; and titanium oxide; as well as any combination of the above.

The anode 27 includes an active anode material. The active anode material can include an artificial-type graphite (AG graphite) and/or a natural-type graphite (NG graphite), at least one binder, and/or at least one carbon additive. AG graphite, also known as synthetic graphite, includes a man-made form of carbon that is produced through high-temperature treatment of carbon materials like petroleum coke and coal tar pitch. NG graphite may include a naturally occurring form of crystalline carbon found in metamorphic and igneous rocks.

The electrolyte 29 provides a medium between the cathode 25 and anode 27 through which lithium ions and the electrolyte 29 travel. The medium may be a liquid, gel, or solid and is capable of conducting the lithium ions between the cathode 25 and the anode 27. The electrolyte 29 wets or otherwise contacts the surfaces of the cathode 25 and anode 27.

In embodiments, the electrolyte 29 includes one or more lithium salts dissolved in non-aqueous organic solvent. The lithium salts may include one or more of the following: lithium hexafluorophosphate (LiPF₆), lithium perchlorate (LiClO₄), lithium tetrachloroaluminate (LiAlCl₄), lithium iodide (LiI), lithium bromide (LiBr), lithium thiocyanate (LiSCN), lithium tetrafluoroborate (LiBF₄), lithium tetraphenylborate (LiB(C₆H₅)₄), lithium bis(oxalato)borate (LiBOB) (LiB(C₂O₄)₂), lithium difluorooxalatoborate (LiBF₂(C₂O₄)), lithium hexafluoroarsenate (LiAsF₆), lithium trifluoromethanesulfonate (LiCF₃SO₃), lithium bis(trifluoromethane)sulfonylimide (LiN(CF₃SO₂)₂), lithium bis(fluorosulfonyl) imide (LiN(F_{S}O₂)₂) (LiSFl), lithium (triethylene glycol dimethy 1 ether)bis(trifluoromethanesulfonyl)imide (Li(G₃)(TFSI), and/or lithium bis(trifluoromethanesulfonyl)azanide (LiTFSA). The lithium salt may be present in the electrolyte 29 at a concentration (moles of salt per liter of solvent (M)) ranging from 0.5M to 2.16M, including all values and ranges therein, for example 1.2M. The electrolyte may include a solvent (e.g., carbonate ester) and may include one or more additives (e.g., fluoroethylene carbonate (FEC), vinylene carbonate (VC), 1,3,2-dioxathiolane 2,2-dioxide (DTD), tris(trimethylsilyl) phosphite (TMSPi), lithium difluoro(oxalate)borate (LiDFOB), tris(trimethylsilyl) borate (TMSPB), and the like).

The electrolyte 29 may additionally include one or more of various alkyl carbonates, such as cyclic carbonates (e.g., ethylene carbonate (EC), propylene carbonate (PC), butylene carbonate (BC), fluoroethylene carbonate (FEC)), linear carbonates (e.g., dimethyl carbonate (DMC), diethyl carbonate (DEC), ethylmethylcarbonate (EMC)), aliphatic carboxylic esters (e.g., methyl formate, methyl acetate, methyl propionate, or other ester-based electrolyte), γ-lactones (e.g., γ-butyrolactone, γ-valerolactone), chain structure ethers (e.g., 1,2-dimethoxyethane, 1,2-diethoxyethane, ethoxymethoxy ethane), and/or cyclic ethers (e.g., tetrahydrofuran, 2-methyltetrahydrofuran), 1,3-dioxolane). In a specific example, the electrolyte includes 1.2M LiPF₆ in a solvent of FEC/dimethyl carbonate (DMC) at a ratio of 1:4 by volume.

Each battery cell 22 may be spaced from an adjacent battery cell 22 by a spacer 34 and/or a pressure sensor 36. The spacer 34 is configured to ensure proper spacing and insulation between individual cells. Additionally, the spacer 34 prevents short circuits, manages pressure, and provides thermal management. Some examples of a spacer 34 can include a plastic spacer, a foam spacer, and/or an aerogel spacer. While a spacer 34 between every battery cell 22 is illustrated in FIG. 2, it will be appreciated that other spacer 34 configurations may be used within the battery pack 12.

As shown in FIG. 2, the pressure sensor 36 is disposed between a first battery cell 22 and a spacer 34. In some cases, the pressure sensor 36 is disposed between a first battery cell 22 and a second battery cell 22. Additionally, the battery pack 12 may include a plurality of pressure sensors 36, and the pressure sensors 36 may be disposed between only some of the battery cells. Each pressure sensor 36 is configured to monitor internal pressure within the battery pack 12 and is designed to be compact, energy-efficient, and capable of providing real-time pressure data. Eventual failure of lithium based battery cells is caused at least partially because some side-reactions consume the electrolyte within the battery cell. As the electrolyte is consumed and dries out, the lithium becomes “mossy.” The “mossy” lithium formed from the side-reactions leads to a change in battery cell thickness and causes irreversible swelling. Irreversible swelling is primarily caused by morphological changes, interphase growth, formation of gas, and passivating layers and is permanent and accumulates over the battery's lifetime leading to a gradual increase in the cell's thickness. In contrast, reversible swelling occurs due to the lithiation and delithiation processes, where lithium ions intercalate into and deintercalate from the electrode materials. Reversible swelling is temporary and the battery returns to its original size after the charge-discharge cycle. By tracking the amount of irreversible swelling, health status of the battery cells 22 and the battery pack 12 can be determined. The pressure sensor(s) 36 can be in communication with the controller 24 and/or a battery management system, for example.

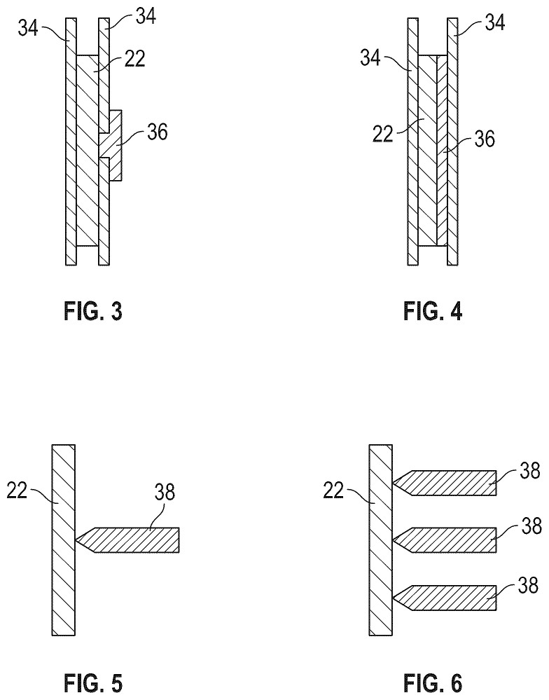

FIG. 3 illustrates an example of the battery cell 22 having a pressure sensor 36. The battery cell 22 is illustrated as being disposed between multiple spacers 34. In this example, the pressure sensor 36 is one-dimensional (1D), where the pressure sensor 36 measures a pressure of the battery cell 22 at one location (shown at a center of a side of the battery cell 22).

FIG. 4 illustrates an example of the battery cell 22 including another type of pressure sensor 36. In this example, the pressure sensor 36 is a two-dimensional (2D) pressure sensor in the form of a pad or a sheet disposed between the battery cell 22 and a spacer 34. The two dimensional pressure sensor 36 can be configured to sense pressure of the battery cell 22 at multiple locations (e.g., an entire side of the battery cell 22).

As shown in FIGS. 5 and 6, the pressure sensor(s) 36 may be combined with a thickness sensor 38 (or a swell sensor) and/or may have dual functionality in measuring a thickness of the battery cell 22. In the example illustrated in FIG. 5, a one-dimensional (1D) thickness sensor 38 is shown located on a side of the battery cell 22. In the example illustrated in FIG. 6, three thickness sensors 38 are shown located on a side of the battery cell 22, where each thickness sensor 38 measures thickness at a different location of the battery cell 22 providing for a two-dimensional (2D) thickness measurement. For end-of-line testing of the battery cell 22, both pressure tracking and thickness tracking may be applied. For on-board tracking, pressure tracking using pressure sensor(s) 36 is preferred.

Referring again to FIG. 2, the battery pack 12 may include multiple pressure sensors 36 disposed at intervals between the battery cells 22. In the example shown in FIG. 2, a pressure sensor 36 is disposed between every three battery cells 22 in the battery pack 12. It will be appreciated that other configurations may be utilized (e.g., a pressure sensor 36 is disposed every two battery cells 22, and so forth). In this example, an average pressure and variation between the pressure sensors 36 may be determined as described below.

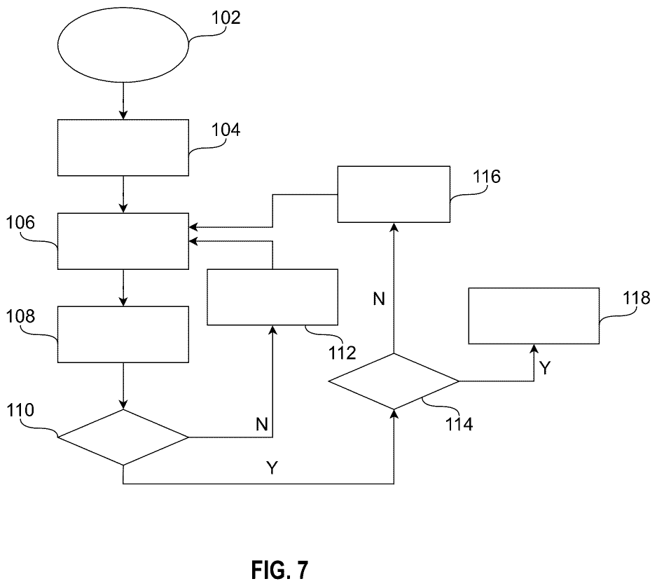

Referring to FIG. 7, a flowchart of the method 100 is shown for predicting battery cell life for the lithium metal-based cells described above. The method 100 begins at block 102 and moves to block 104.

Block 104 depicts receiving a predetermined end-of-life pressure P₁ for a lithium-based battery cell. The lithium-based battery cell may have a finalized electrolyte amount and electrode amount. The controller 24 can receive the predetermined end-of-life pressure P₁ as a value determined from lab testing and/or a predetermined empirical model prediction. The predetermined end-of-life pressure P₁ can be determined using a Li metal-based battery cell with a fixed cell design having a finalized electrolyte and electrode amount. The method then moves to block 106.

Block 106 depicts tracking an onboard battery cell pressure change using a pressure sensor 36 disposed between a first battery cell 22 and a second battery cell 22 in the vehicle battery pack 12. The controller 24 can receive updated pressure measurements and determine the pressure change from the irreversible swelling by comparing present and past pressure measurements in the same state of charge (SOC) value. In embodiments, determining the pressure P between the multiple battery cells at least partially based on the predetermined end-of-life pressure and the onboard battery cell pressure change occurs when a state of charge (SOC) of the battery cell(s) 22 reaches a certain value, which is preferred to be 100%.

In an example, an average pressure measurement may be tracked and/or determined. In the example illustrated in FIG. 2, the battery pack 12 may include multiple battery cells 22 with multiple pressure sensors 36 disposed between some of the battery cells 22. In the specific instance shown in FIG. 2, the battery pack 12 includes fifteen battery cells 22 with a pressure sensor 36 disposed between every three battery cells 22 and on the end battery cells 22 measuring a pressure Pₐ, P_{b}, P_{c}, P_{d}, Pₑ, and P_{f}. If P_{b}=P_{c}=P_{d}=Pₑ or if a variation between the pressure measurements Pₐ, P_{b}, P_{c}, P_{d}, Pₑ, P_{f} is less than σ (e.g., σ=0.02P1) as determined by controller 24, then it may be determined that all the battery cells 22 have similarly swelled. In these cases, either Pₐ or P_{f} may be used as pressure P. If a variation (e.g., greater than σ) between pressures P_{b}, P_{c}, P_{d}, and Pₑ is determined, the pressure sensor number is determined by cell variation. In this case, for cells with variation of a, the value N could be determined by the equation (P₀/P₁−a)*(N−1)+P₀/P₁>P₀*N−(1−P₀/P₁). In this equation, N is the least number of cells sharing one pressure sensor. The method 100 then moves to block 108.

Block 108 depicts determining a pressure P between the multiple battery cells at least partially based on the predetermined end-of-life pressure P₁ and the onboard battery cell pressure change. The pressure P represents a pressure between multiple battery cells 22 at any one time. The controller 24 may be used to determine the pressure P using at least one pressure sensor 36. The method then moves to block 110.

Block 110 depicts determining if the pressure P is greater than a pre-end-of-life warning pressure P₀. The pre-end-of-life warning pressure P₀ is a pressure correlated with a battery life that still has capacity but is determined to be near “sudden death” or end-of-life of the battery cell 22 and/or battery pack 12. The controller can determine a value of the pre-end-of-life warning pressure P₀ based on the predetermined end-of-life pressure P₁. For example, P₀ may be determined to be 80% of the predetermined end-of-life pressure P₁ (e.g., 0.8P₁) or 90% of the predetermined end-of-life pressure P₁ (e.g., 0.9P₁). It will be appreciated that P₀ may be determined to be other amounts (e.g., 95%, 85%, 75%, 70%, and so forth) of the predetermined end-of-life pressure P₁ or may be determined other suitable ways.

In some instances, a capacity check of the battery cell 22 and/or the battery pack 12 may be determined by measuring reversible swelling. Pressure changes due to reversible swelling are similar throughout a cycle of the battery cell 22 until near failure of the battery cell 22. For example, an initial thickness/pressure gap between each of the battery cells 22 ΔP₀ and a usable capacity Q₀ may be determined between 0% and 100% state of charge (SOC) of the fresh battery cells 22. Once the battery pack 12 and battery cells 22 are onboard, and in one specific cycle, a pressure can be recorded to determine a gap ΔPᵢ, where the pressure is measured between 0% and 100% of the state of charge (SOC). A usable capacity Qᵢ, determined from measure of reversible swelling, can be calculated as Qᵢ=ΔPᵢ/ΔP₀*Q₀. If the pressure P is not greater than the pre-end-of-life warning pressure P₀, then the method 100 moves to block 112. If the pressure P is greater than the pre-end-of-life warning pressure P₀, then the method 100 moves to block 114.

Block 112 depicts providing the pressure P to at least partially determine the onboard battery cell pressure change if the pressure P is less than the pre-end-of-life warning pressure P₀. In this case, the pressure P may be provided to controller 24 at block 106 to provide the pressure P for tracking the onboard battery cell pressure.

Block 114 depicts determining if the pressure P is greater than or equal to the predetermined end-of-life pressure P₁ when the pressure P is determined to be greater than the pre-end-of-life warning pressure P₀. Controller 24 can determine if the pressure P is greater than or equal to the predetermined end-of-life pressure P₁. If the pressure P is not greater than the predetermined end-of-life pressure P₁, then the method 100 moves to block 116. If the pressure P is greater than the predetermined end-of-life pressure P₁, then the method 100 moves to block 118.

Block 116 depicts providing a pre-warning signal indication to at least partially determine the onboard battery cell pressure change if the pressure P is less than the predetermined end-of-life pressure P₁. The controller 24 can provide to block 106 a pre-warning signal and/or an indication that the pressure P is greater than the pre-end-of-life warning pressure P₀.

Block 118 depicts providing an indication of battery cell failure if the pressure P is greater than or equal to the predetermined end-of-life pressure P₁. In this case, the controller 24 can provide, for example to the HMI 26 and/or the HUD 28, and thus to a vehicle occupant, that the predetermined end-of-life pressure P₁ has been reached and that at least one battery cell 22 and/or the battery pack 12 has failed and cannot be cycled. The method 100 then ends.

The method 100 of the present disclosure is advantageous and beneficial over the prior art. The method and subject matter disclosed herein are designed to link a battery cell life with swelling status of the battery cells because irreversible swelling of the battery cell is at least somewhat linear compared to the number of cycles of the battery cell. By using this reliable and detectable method, the lithium battery cell life becomes predictable. This method may be utilized for lithium iron phosphate (LFP)-type batteries as well as lithium sulfur (Li-S)-type batteries, nickel cobalt manganese (NCM/Li)-type batteries.

This description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

What is claimed is:

1. A method for predicting battery cell life for lithium-based battery cells, comprising:
receiving a predetermined end-of-life pressure P₁ for a lithium-based battery cell, wherein the lithium-based battery cell is disposed in a vehicle battery pack;
tracking an onboard battery cell pressure change using a pressure sensor disposed between a first battery cell and a second battery cell in the vehicle battery pack;
determining a pressure P between the first battery cell and the second battery cell at least partially based on the predetermined end-of-life pressure P₁ and the onboard battery cell pressure change;
determining if the pressure P is greater than a pre-end-of-life warning pressure P₀;
if the pressure P is less than the pre-end-of-life warning pressure P₀, then providing the pressure P to at least partially determine the onboard battery cell pressure change;
if the pressure P is greater than the pre-end-of-life warning pressure P₀, then determining if the pressure P is greater than or equal to the predetermined end-of-life pressure P₁;
if the pressure P is less than the predetermined end-of-life pressure P₁, then providing a pre-warning signal indication to at least partially determine the onboard battery cell pressure change; and
if the pressure P is greater than or equal to the predetermined end-of-life pressure P₁, then providing an indication of battery cell failure.

2. The method of claim 1, wherein the predetermined end-of-life pressure P₁ is determined using lab testing.

3. The method of claim 1, wherein the predetermined end-of-life pressure P₁ is predetermined using empirical model prediction.

4. The method of claim 1, wherein the pressure sensor includes a one-dimensional (1D) pressure sensor.

5. The method of claim 1, wherein the pressure sensor includes a two-dimensional (2D) pressure sensor.

6. The method of claim 1, wherein determining the pressure P between the first battery cell and the second battery cell is at least partially based on the predetermined end-of-life pressure and the onboard battery cell pressure change occurs when a state of charge (SOC) is 100%.

7. The method of claim 1, wherein determining a pressure P includes determining a thickness of the first battery cell and the second battery cell using at least one thickness sensor.

8. The method of claim 7, wherein determining the thickness of the first battery cell and the second battery cell includes using a one-dimensional (1D) thickness sensor.

9. The method of claim 7, wherein determining the thickness of the first battery cell and the second battery cell includes using multiple thickness sensors.

10. The method of claim 1, wherein determining the pressure P between the first battery cell and the second battery cell includes determining an average pressure and variation between at least three battery cells.

11. The method of claim 1, wherein the pressure P is caused by irreversible swelling of the first battery cell and the second battery cell.

12. The method of claim 1, wherein the pre-end-of-life warning pressure P₀ is predetermined to be 80% of the predetermined end-of-life pressure P₁.

13. The method of claim 1, wherein the pre-end-of-life warning pressure P₀ is predetermined to be 90% of the predetermined end-of-life pressure P₁.

14. The method of claim 1, wherein the lithium-based battery cell includes a lithium-based anode.

15. The method of claim 1, wherein the lithium-based battery cell includes at least one of a LFP, NCM/NCA/NCMA/NMx, LMR, or a sulfur-based cathode.

16. The method of claim 1, wherein the lithium-based battery cell includes an ester-based electrolyte.

17. The method of claim 1, wherein a usable capacity Qᵢ of the lithium-based battery cell is determined by measuring reversible swelling.

18. A method for predicting battery cell life for lithium metal-based cells, comprising:
receiving a predetermined end-of-life pressure P₁ for a lithium-based battery cell having a finalized electrolyte amount and electrode amount, the lithium-based battery cell disposed in a vehicle battery pack;
tracking an onboard battery cell pressure change using a pressure sensor disposed between a first battery cell and a second battery cell in the vehicle battery pack when a state of charge (SOC) of the lithium-based battery cell is 100%;
determining a pressure P between the first battery cell and the second battery cell at least partially based on the predetermined end-of-life pressure and the onboard battery cell pressure change;
determining if the pressure P is greater than a pre-end-of-life warning pressure P₀;
if the pressure P is less than the pre-end-of-life warning pressure P₀, then providing a state of health (SOH) battery cell pressure to at least partially determine the onboard battery cell pressure change;
if the pressure P is greater than the pre-end-of-life warning pressure P₀, then determining if the pressure P is greater than or equal to the predetermined end-of-life pressure P₁;
if the pressure P is less than the predetermined end-of-life pressure P₁, then providing a pre-warning signal indication to at least partially determine the onboard battery cell pressure change; and
if the pressure P is greater than or equal to the predetermined end-of-life pressure P₁, then providing an indication of battery cell failure.

19. The method of claim 1, wherein determining the pressure P between the first battery cell and the second battery cell includes determining an average pressure between at least two battery cells.

20. A system for predicting battery cell life for lithium metal-based cells, the system comprising:
a human-machine interface; and
a controller in electrical communication with the human machine interface, wherein the controller is programmed to
receive a predetermined end-of-life pressure P₁ for a lithium-based battery cell having a finalized electrolyte amount and electrode amount, the lithium-based battery cell disposed in a vehicle battery pack;
track an onboard battery cell pressure change using a pressure sensor disposed between multiple battery cells in the vehicle battery pack when a state of charge (SOC) of the lithium-based battery cell is 100%;
determine a pressure P between the multiple battery cells at least partially based on the predetermined end-of-life pressure and the onboard battery cell pressure change;
determine if the pressure P is greater than a pre-end-of-life warning pressure P₀;
if the pressure P is less than the pre-end-of-life warning pressure P₀, then provide a state of health (SOH) battery cell pressure to at least partially determine the onboard battery cell pressure change;
if the pressure P is greater than the pre-end-of-life warning pressure P₀, then determine if the pressure P is greater than or equal to the predetermined end-of-life pressure P₁;
if the pressure P is less than the predetermined end-of-life pressure P₁, then provide a pre-warning signal indication to at least partially determine the onboard battery cell pressure change; and
if the pressure P is greater than or equal to the predetermined end-of-life pressure P₁, then provide an indication of battery cell failure.
